(19) United States
(12) Patent Application Publication
(10) Pub. No.: US 2024/0136157 A1
(43) Pub. Date: Apr. 25, 2024

(54) SUBSTRATE PROCESSING APPARATUS AND SUBSTRATE PROCESSING METHOD

(71) Applicant: SEMES CO., LTD., Cheonan-si (KR)

(72) Inventors: Je Ho KIM, Cheonan-si (KR); Tae Suk JUNG, Cheonan-si (KR)

(73) Assignee: SEMES CO., LTD., Cheonan-si (KR)

(21) Appl. No.: 18/381,151

(22) Filed: Oct. 16, 2023

(30) Foreign Application Priority Data
Oct. 18, 2022 (KR) 10-2022-0134833

(51) Int. Cl. H01J 37/32; H01L 21/67; H01L 21/683; H01L 21/687

(52) U.S. Cl. CPC H01J 37/32633; H01J 37/3244; H01L 21/67069; H01L 21/67103; H01L 21/6833; H01L 21/68742; H01J 2237/334

(57) ABSTRACT

Proposed is a substrate processing apparatus, including a housing configured to provide a processing space therein, a substrate support unit configured to support a substrate within the processing space, and a baffle unit provided to surround a circumference of the substrate support unit. The baffle unit includes a baffle plate provided to surround the circumference of the substrate support unit and having at least one slit therein, and a drive member that lifts and moves the baffle plate, and the housing is provided in a shape capable of changing a size of a space between the processing space and the baffle plate according to a lifting movement of the baffle plate.

### CROSS REFERENCE TO RELATED APPLICATION

The present application claims priority to Korean Patent Application No. 10-2022-0134833, filed Oct. 19, 2022, the entire contents of which is incorporated by reference herein for all purposes.

### BACKGROUND OF THE INVENTION

### 1. Field of the Invention

The present disclosure relates to a substrate processing apparatus and a substrate processing method.

### 2. Description of the Related Art

In general, the manufacturing process of semiconductor devices involves steps such as deposition for forming a film on a semiconductor wafer (hereinafter referred to as “substrate”), chemical/mechanical polishing for planarizing the film, photolithography for creating a photoresist pattern on the film, etching for forming the film into a pattern having electrical properties using the photoresist pattern, ion implantation for implanting specific ions into a predetermined region of the substrate, cleaning for removing impurities on the substrate, and inspection for inspecting the surface of the substrate on which a film or pattern is formed.

Plasma may be used in some of the above-mentioned substrate processing steps. For example, plasma may be used for etching, deposition, or dry cleaning. Plasma is generated by a strong, very high temperature electric field or RF electromagnetic fields, and refers to an ionized gas state composed of ions, electrons, or radicals. Dry cleaning, asking, or etching using plasma are performed when ion or radical particles included in the plasma collide with a substrate.

At this time, the plasma existing around the substrate may be non-uniformly distributed due to various environmental factors. Non-uniform plasma distribution may result in non-uniform treatment of the substrate.

FIGS. 3 and 4 are views showing a conventional baffle unit. FIG. 3 is a cross-sectional view showing the configuration of a substrate support member 210 and a baffle unit 180 surrounding the substrate support member 210, and FIG. 4 is a view showing the process of discharging process by-products by such a configuration.

Referring to FIGS. 3 and 4, the conventional baffle unit 180 is fixedly disposed to surround the outer circumference of the substrate support member 210. As the position of the baffle unit 180 is fixed, it is difficult to control conductance that affects plasma processing, and it is difficult to ensure a process margin through residence time control of process gases and process by-products. In addition, since the location of a control is relatively far from the substrate, fine process control is impossible.

### SUMMARY OF THE INVENTION

Accordingly, the present disclosure has been made keeping in mind the above problems occurring in the related art, and the present disclosure is intended to provide a substrate processing apparatus and a substrate processing method capable of increasing processing efficiency in plasma processing of a substrate.

In addition, an objective of the present disclosure is to provide a substrate processing apparatus capable of controlling the distribution of plasma existing around a substrate in order to generate uniform plasma in a processing space.

Objectives of the present disclosure are not limited thereto, and other objectives not mentioned will be clearly understood by those skilled in the art from the following description.

In order to achieve the above objective, according to an embodiment of the present disclosure, there is provided a substrate processing apparatus including: a housing configured to provide a processing space therein; a substrate support unit configured to support a substrate within the processing space; and a baffle unit provided to surround a circumference of the substrate support unit, wherein the baffle unit may include: a baffle plate provided to surround the circumference of the substrate support unit and having at least one slit therein; and a drive member that lifts and moves the baffle plate, and the housing may be provided in a shape capable of changing a size of a space between the processing space and the baffle plate according to a lifting movement of the baffle plate.

According to an embodiment of the present disclosure, there may be provided a substrate processing apparatus including: a housing configured to provide a processing space therein; a substrate support unit configured to support a substrate within the processing space; a gas supply unit configured to supply a process gas to the processing space; a plasma generation unit configured to generate plasma from the process gas; and a baffle unit provided to surround a circumference of the substrate support unit, wherein the baffle unit may include: a baffle plate provided to surround the circumference of the substrate support unit and having at least one slit therein; and a drive member that lifts and moves the baffle plate, and an inner wall of the housing may include an inclined surface so that a changing occurs in a distance between the inner wall of the housing and the baffle plate according to a lifting movement of the baffle plate.

According to an embodiment of the present disclosure, there may be provided a substrate processing method, including: plasma processing a substrate by supplying plasma to a substrate placed on a substrate support unit; moving a baffle plate provided to surround the substrate support unit to adjust a vertical position of the baffle plate; and exhausting a processing space for exhausting the processing space. In the substrate processing method, plasma density above the baffle plate may be controlled by adjusting the vertical position of the baffle plate, and at least a portion of an inner surface of a processing space may be formed as an inclined surface so that a space between the baffle plate and the processing space may be variable according to a lifting movement of the baffle plate.

According to the present disclosure, plasma density can be adjusted by configuring a baffle unit that allows a process gas provided for substrate processing to stay in a process space for a predetermined period of time to be movable up and down.

Furthermore, according to the embodiments of the present disclosure, internal conductance can be controlled by forming an inclination on the inner surface of a housing to utilize the fact that the space secured between the inner wall of the housing and the baffle unit changes according to the movement of the baffle unit.

The effects of the present disclosure are not limited to the above effects, and effects not mentioned will be clearly understood by those skilled in the art from this specification and the accompanying drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view of a substrate processing apparatus according to an embodiment of the present disclosure;

FIG. 2 is a cross-sectional view of a substrate processing apparatus according to another embodiment of the present disclosure;

FIGS. 3 and 4 are partially enlarged views showing a conventional baffle unit;

FIGS. 5 to 8 are partially enlarged views showing a baffle unit according to an embodiment of the present disclosure; and

FIG. 9 is a flowchart showing a substrate processing method according to an embodiment of the present disclosure.

### DETAILED DESCRIPTION OF THE INVENTION

Hereinafter, embodiments of the present disclosure will be described in detail with reference to the accompanying drawings so that those skilled in the art can easily carry out the present disclosure.

However, the present disclosure may be embodied in many different forms and is not limited to the embodiments described herein.

In describing the embodiments of the present disclosure, when it is determined that a detailed description of a related known function or configuration may unnecessarily obscure the subject matter of the present disclosure, the specific description will be omitted, and parts with similar functions and actions will use the same reference numerals throughout the drawings.

Since at least some of the terms used in the specification are defined in consideration of functions in the present disclosure, they may vary according to user, operator intention, custom, and the like. Therefore, the terms should be interpreted based on the contents throughout the specification.

In addition, in this specification, the singular form also includes the plural form unless otherwise specified in the phrase. In the specification, when it is said to include a certain component, this means that it may further include other components without excluding other components unless otherwise stated. When a part is said to be connected (or coupled) with another part, this includes not only the case of being directly connected (or coupled), but also the case of being indirectly connected (or coupled) with another part in between.

Meanwhile, in the drawings, the size or shape of components, and thickness of lines may be somewhat exaggerated for convenience of understanding.

The embodiments of the present disclosure are described with reference to schematic illustrations of idealized embodiments of the present disclosure. Accordingly, variations from the shape of the illustration, for example, variations in manufacturing method and/or tolerances, are fully expected. Therefore, the embodiments of the present disclosure are not to be described as being limited to specific shapes of regions illustrated as illustrations, but to include deviations in shape, and the components described in the drawings are purely schematic and their shape is not intended to illustrate the exact shape of the components nor is it intended to limit the scope of the present disclosure.

When an element or layer is referred to as “on” another element or layer, it includes both the case where another element or layer is intervened as well as directly on another element or layer. On the other hand, when an element is referred to as “directly on” or “directly on”, it indicates that another element or layer is not intervened.

The spatially relative terms “below”, “beneath”, “lower”, “above”, “upper”, etc. may be used to easily describe the correlation between one element or component and another element or component as shown in the drawings. The spatially relative terms should be understood as encompassing different orientations of elements in use or operation in addition to the orientations shown in the drawings. For example, when elements shown in the drawings are reversed, elements described as “below” or “beneath” other elements may be placed “above” the other elements. Thus, the exemplary term “below” may include orientations of both below and above. Elements may also be oriented in other orientations, and thus spatially relative terms may be interpreted according to orientation.

Although first, second, etc. are used to describe various elements, components and/or sections, it is needless to say that these elements, components and/or sections are not limited by these terms. These terms are only used to distinguish one element, component or section from another element, component or section. Thus, it is needless to say that first element, first component, or first section referred to below may be a second element, second component, or second section within the technical spirit of the present disclosure.

Hereinafter, embodiments of the present disclosure will be described in detail with reference to the accompanying drawings. In describing with reference to the accompanying drawings, regardless of the reference numerals, the same or corresponding components are given the same reference numerals, and duplicate descriptions thereof will be omitted.

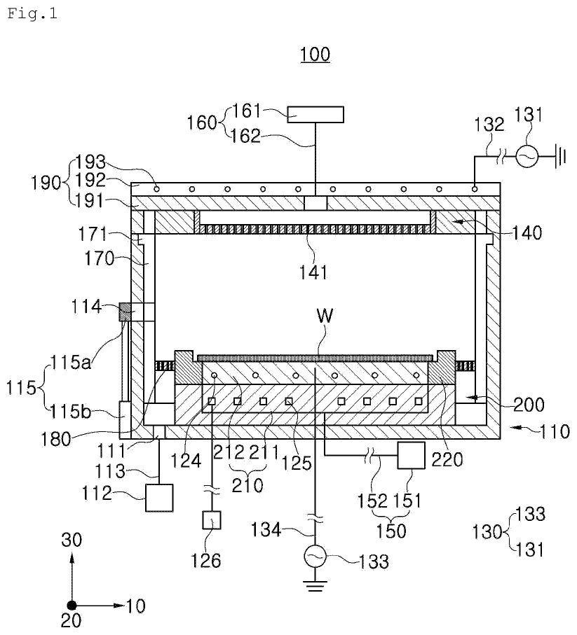

FIG. 1 is a cross-sectional view schematically showing the structure of a substrate processing apparatus according to an embodiment of the present disclosure.

Referring to FIG. 1, a substrate processing apparatus 100 may include a housing 110, a substrate support unit 200, a plasma generation unit 130, a shower head unit 140, a first gas supply unit 150, a second gas supply unit 160, a wall liner unit 170, a baffle unit 180, and an upper module 190.

The substrate processing apparatus 100 is a system that processes a substrate W (e.g., a wafer) by using an etching process (e.g., a dry etching process) in a vacuum environment. The substrate processing apparatus 100 may process the substrate W using, for example, a plasma process.

The housing 110 provides a processing space in which the plasma process is performed. The housing 110 may have an exhaust hole 111 at a lower portion thereof.

The exhaust hole 111 may be connected to an exhaust line 113 in which a pump 112 is mounted. The exhaust hole 111 may discharge reaction by-products produced during the plasma process and gas remaining inside the housing 110 to the outside of the housing 110 through the exhaust line 113. In this case, the inner space of the housing 110 may be decompressed to a predetermined pressure.

The housing 110 may have an opening 114 formed on the sidewall thereof. The opening 114 may function as a passage through which the substrate W enters and exits the housing 110. The opening 114 may be configured to be opened and closed by a door assembly 115.

The door assembly 115 may include an outer door 115a and a door actuator 115b. The outer door 115a is provided on the outer wall of the housing 110. The outer door 115a may be moved in a vertical direction (i.e., in a third direction 30) by means of the door actuator 115b. The door actuator 115b may operate using a motor, hydraulic cylinder, pneumatic cylinder, or the like.

The substrate support unit 200 is installed in the lower inner region of the housing 110. The substrate support unit 200 may support the substrate W using electrostatic force. However, the present embodiment is not limited thereto. The substrate support unit 200 may support the substrate W in various ways such as mechanical clamping, vacuum, and the like.

When the substrate support unit 200 supports the substrate W using electrostatic force, the substrate support unit 200 may include an electrostatic chuck (ESC) 210 including a base component 211 and a chucking component 212.

The base component 211 supports the chucking component. The base component 211 may be made of, for example, an aluminum component and provided as an aluminum base plate.

The chucking component 212 supports the substrate W placed thereon using electrostatic force. The chucking component 212 may be made of ceramic components and provided as a ceramic plate or a ceramic puck, and may be combined with the base component 211 to be fixed on the base component 211.

An insulating layer 213 made of an insulator may be formed between the base component 211 and the chucking component 212 formed thereon.

A focus ring 220 may be disposed on an edge area of the substrate support unit 200. The focus ring 220 has a ring shape and may be disposed along the circumference of the electrostatic chuck 210. An upper surface of the focus ring 220 may have an outer portion higher than an inner portion. For example, the inner portion of the upper surface of the focus ring 220 may be positioned at the same level as the upper surface of the chucking component 212. The inner portion of the upper surface of the focus ring 220 may support an edge area of the substrate W supported by the chucking component 212. The focus ring 220 may control the electric field so that the plasma density is uniformly distributed over the entire area of the substrate W. As a result, plasma is uniformly formed over the entire area of the substrate W so that each area of the substrate W may be uniformly etched.

The first gas supply unit 150 may supply heat transfer gas to the lower surface of the substrate W. The heat transfer gas serves as a medium to help heat exchange between the substrate W and the electrostatic chuck 210. The entire temperature of the substrate W may be made uniform by the heat transfer gas. The heat transfer gas contains an inert gas. For example, the heat transfer gas may include helium (He) gas. The first gas supply unit 150 may include a first gas supply source 151 and a first gas supply line 152.

The first gas supply source 151 may supply He gas as a first gas. The first gas from the first gas supply source 151 may be supplied to the lower surface of the substrate W through the first gas supply line 152.

A heating member 124 and a cooling member 125 are provided to maintain a process temperature of the substrate W when an etching process is in progress inside the housing 110. For this purpose, the heating member 124 may be provided as a heating wire, and the cooling member 125 may be provided as a cooling line through which a refrigerant flows.

The heating member 124 and the cooling member 125 may be installed inside the electrostatic chuck 210 so that the substrate W may maintain the process temperature. As an example, the heating member 124 may be installed inside the chucking component 122, and the cooling member 125 may be installed inside the base component 121.

Meanwhile, the cooling member 125 may receive a refrigerant using a chiller 126. The chiller 126 may be installed outside the housing 110.

The plasma generation unit 130 generates plasma from gas remaining in a discharge space. At this time, the discharge space means a space above the electrostatic chuck 210 in the inner space of the housing 110.

The plasma generation unit 130 may generate plasma in the discharge space inside the housing 110 using an inductively coupled plasma (ICP) source. In this case, the plasma generation unit 130 may use an antenna unit 193 installed on an upper module 190 as an upper electrode and use the electrostatic chuck 210 as a lower electrode.

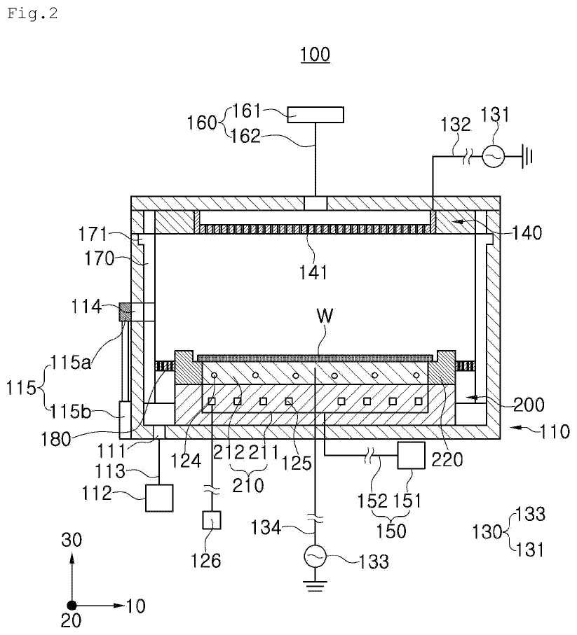

However, the present embodiment is not limited thereto. The plasma generation unit 130 may generate plasma in the discharge space inside the housing 110 using a capacitively coupled plasma (CCP) source. In this case, as shown in FIG. 2, the plasma generation unit 130 may use the shower head unit 140 as an upper electrode and the electrostatic chuck 210 as a lower electrode. FIG. 2 is a cross-sectional view schematically showing the structure of a substrate processing apparatus according to another embodiment of the present disclosure.

The description will be continued with reference to FIG. 1 again.

The plasma generation unit 130 may include an upper electrode, a lower electrode, an upper power source 131 and a lower power source 133.

The upper power source 131 applies power to the upper electrode, that is, the antenna unit 193. Such an upper power source 131 may be provided to control the characteristics of plasma. The upper power source 131 may be provided to adjust ion bombardment energy, for example.

Although a single upper power source 131 is shown in FIG. 1, it is also possible to have a plurality of upper power sources 131 in this embodiment. When the plurality of upper power sources 131 are provided, the substrate processing apparatus 100 may further include a first matching network (not shown) electrically connected to the plurality of upper power sources.

The first matching network may match frequency powers of different magnitudes input from each upper power source and apply the matched frequency powers to the antenna unit 193.

Meanwhile, a first impedance matching circuit (not shown) may be provided on a first transmission line 132 connecting the upper power source 131 and the antenna unit 193 for the purpose of impedance matching.

The first impedance matching circuit may act as a lossless passive circuit to effectively (i.e., maximally) transfer electrical energy from the upper power source 131 to the antenna unit 193.

The lower power source 133 applies power to the lower electrode, that is, the electrostatic chuck 210. The lower power source 133 may serve as a plasma source for generating plasma or may serve to control characteristics of plasma together with the upper power source 131.

Although a single lower power source 133 is shown in FIG. 1, it is also possible to have a plurality of lower power sources 133 in this embodiment like the upper power source 131. When the plurality of lower power sources 133 are provided, the substrate processing apparatus 100 may further include a second matching network (not shown) electrically connected to the plurality of lower power sources.

The second matching network may match frequency powers of different magnitudes input from each lower power source and apply the matched frequency powers to the electrostatic chuck 210.

Meanwhile, a second impedance matching circuit (not shown) may be provided on a second transmission line 134 connecting the lower power source 133 and the electrostatic chuck 210 for the purpose of impedance matching.

Like the first impedance matching circuit, the second impedance matching circuit may act as a lossless passive circuit to effectively (i.e., maximally) transfer electrical energy from the lower power source 133 to the electrostatic chuck 210.

The shower head unit 140 may be vertically opposed to the electrostatic chuck 210 inside the housing 110. The shower head unit 140 may include a plurality of gas feeding holes 141 to inject gas into the housing 110, and may be provided to have a larger diameter than the electrostatic chuck 210.

Meanwhile, the shower head unit 140 may be made of a silicon component, or may be made of a metal component.

The second gas supply unit 160 supplies process gas (second gas) into the housing 110 through the shower head unit 140. The second gas supply unit 160 may include a second gas supply source 161 and a second gas supply line 162.

The second gas supply source 161 supplies an etching gas used to process the substrate W as a process gas. The second gas supply source 161 may supply a gas containing a fluorine component (e.g., a gas such as SF6 or CF4) as an etching gas.

A single second gas supply source 161 may be provided to supply etching gas to the shower head unit 140. However, the present embodiment is not limited thereto. A plurality of second gas supply sources 161 may be provided to supply process gas to the shower head unit 140.

The second gas supply line 162 connects the second gas supply source 161 and the shower head unit 140. The second gas supply line 162 transfers the process gas supplied from the second gas supply source 161 to the shower head unit 140 so that the etching gas may flow into the housing 110.

Meanwhile, when the shower head unit 140 is divided into a center zone, a middle zone, and an edge zone, the second gas supply unit 160 may further include a gas distributor (not shown) and a gas distribution line (not shown) to supply process gas to each area of the shower head unit 140.

The gas distributor distributes the process gas supplied from the second gas supply source 161 to each area of the shower head unit 140. The gas distributor may be connected to the second gas supply source 161 through the second gas supply source 161.

The gas distribution line connects the gas distributor and each area of the shower head unit 140. Through the gas distribution line, the process gas distributed by the gas distributor may be transferred to each area of the shower head unit 140.

Meanwhile, the second gas supply unit 160 may further include a third gas supply source (not shown) for supplying deposition gas.

The third gas supply source supplies gas to the shower head unit 140 to protect the side surface of the substrate W pattern and enable anisotropic etching. The third gas supply source may supply a gas such as C4F8 or C2F4 as a deposition gas.

The wall liner unit 170 protects the inner surface of the housing 110 from arc discharge generated during process gas excitation and impurities produced during a substrate processing process. The wall liner unit 170 may be provided inside the housing 110 in a cylindrical shape with upper and lower portions thereof open. Optionally, the wall liner unit 170 may not be provided.

The wall liner unit 170 may be provided adjacent to the inner wall of the housing 110. The wall liner unit 170 may have a support ring 171 thereon. The support ring 171 protrudes from the upper part of the wall liner unit 170 in an outward direction (i.e., in a first direction 10), and is placed on the upper side of the housing 110 to support the wall liner unit 170.

The baffle unit 180 serves to exhaust plasma process by-products, unreacted gases, and the like. The baffle unit 180 may be installed between the inner wall of the housing 110 and the electrostatic chuck 210. The baffle unit 180 may be provided in an annular ring shape and may include a plurality of through holes penetrating in a vertical direction (i.e., in a third direction 30). The baffle unit 180 may control the flow of process gas depending on the number and shape of through holes.

The upper module 190 is installed to cover the open top of the housing 110. The upper module 190 may include a window member 191, an antenna member 192 and an antenna unit 193.

The window member 191 is formed to cover the top of the housing 110 to seal the inner space of the housing 110. The window member 191 may be provided in a plate (e.g., disc) shape, and may be made of an insulating material (e.g., alumina (Al2O3)).

The window member 191 may be formed by including a dielectric window. The window member 191 may have a through hole through which the second gas supply line 162 is inserted. A coating film may be formed on the surface of the window member 191 to suppress generation of particles when a plasma process is performed inside the housing 110.

The antenna member 192 is installed on top of the window member 191, and may be provided with a space of a predetermined size so that the antenna unit 193 may be disposed therein.

The antenna member 192 may be formed in a cylindrical shape with an open bottom, and may be provided to have a diameter corresponding to that of the housing 110. The antenna member 192 may be provided to be detachable from the window member 191.

The antenna unit 193 functions as an upper electrode and is equipped with a coil provided to form a closed loop. The antenna unit 193 generates a magnetic field and an electric field inside the housing 110 based on power supplied from the upper power source 131 to excite gas introduced into the housing 110 through the shower head unit 140 into plasma.

The antenna unit 193 may be equipped with a planar spiral coil. However, the present embodiment is not limited thereto. The structure or size of the coil may be variously changed by those skilled in the art.

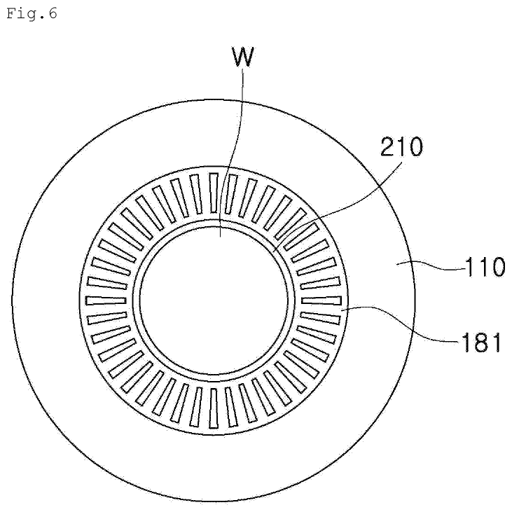

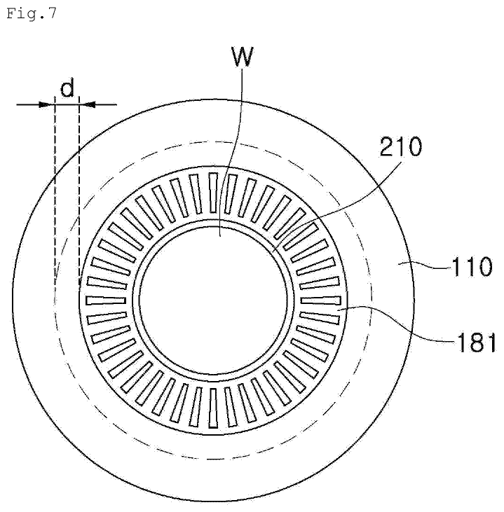

FIGS. 5 to 8 are partially enlarged views showing a baffle unit according to an embodiment of the present disclosure. FIG. 5 is a cross-sectional view showing the baffle unit, and FIGS. 6 and 7 show top views according to the position of a baffle plate 181.

As shown in FIG. 5, the baffle unit 180 according to an embodiment of the present disclosure may include: the baffle plate 181 provided to surround the circumference of the electrostatic chuck 210; and a drive member 182 that lifts and moves the baffle plate 181.

The baffle plate 181 may be disposed to move up and down along the outer circumference of the electrostatic chuck 210 by the drive member 182. An inner wall of the housing 110, corresponding to the moving section of the baffle plate 181 by the drive member 182, may include an inclined surface s. This is a configuration for making a change in the space between the processing space and the baffle plate 181 as the baffle plate 181 moves up and down. As shown in FIG. 5, the shape of the inclination may be a shape in which the periphery becomes narrower from bottom to top.

Alternatively, the shape of the inclination may be a shape in which the periphery becomes wider from bottom to top.

Due to this shape, a gap d and the space between the inner wall of the housing 110 and the baffle plate 181 may vary depending on the position of the baffle plate 181.

For example, when the periphery of the inclined surface s of the housing 110 narrows from bottom to top, and the baffle plate 181 is located at the uppermost end of the inclined surface s, a space may not exist between the baffle plate 181 and the inner wall of the housing 110 as shown in FIG. 6. Accordingly, the processing space may be limited to the space above the baffle plate 181, and process by-products and unused process gas generated during the plasma process may be discharged only through slits of the baffle plate 181.

On the other hand, when the baffle plate 181 is positioned below the uppermost end of the inclined surface s, the gap d and a space between the baffle plate 181 and the inner wall of the housing 110 exist, as shown in FIG. 7. Accordingly, even though the processing space is limited to the space above the baffle plate 181, process by-products P and unused process gas generated during the plasma process may be discharged not only through the slits of the baffle plate 181 but also through the space created between the baffle plate 181 and the inner wall of the housing 110.

That is, when the inclined surface s formed on the inner wall of the housing 110 has a shape in which the periphery becomes narrower from bottom to top, the gap d and space between the baffle plate 181 and the inner wall of the housing 110 may increase as the distance at which the baffle plate 181 descends downward from the uppermost end of the inclined surface s increases. Accordingly, a flow screen effect by the baffle plate 181 may be weakened.

Therefore, if the distance (gap d) between the baffle plate 181 and the inner wall of the housing 110 is adjusted by controlling the position of the baffle plate 181, depending on the size of the gap, plasma confinement and chamber conductance may be controlled.

In terms of plasma confinement, the higher the baffle plate 181 is positioned (the smaller the gap and space between the baffle plate 181 and the inner wall of the housing), the stronger the binding force may be, whereas the lower the baffle plate 181 is positioned (the larger the gap and space between the baffle plate 181 and the inner wall of the housing), the weaker the binding force may be.

In terms of chamber conductance, by reducing the chamber conductance, the residence time of process gases and process by-products may be increased, which improves the recess selectivity of the substrate to ensure process margins in the Punch, Not Open area of critical dimension (CD).

When the inclined surface s formed on the inner wall of the housing 110 has a shape in which the periphery is widened from bottom to top, the effect opposite to that described above will be obtained.

Meanwhile, although not shown in detail, the substrate processing apparatus according to an embodiment of the present disclosure may further include: a position sensor to detect vertical position of baffle plate 181; and a controller for controlling the vertical position, that is, the height, of the baffle plate 181.

The controller (not shown) may control the position of the baffle plate 181 by monitoring the vertical position of the baffle plate 181 by means of a position sensor and controlling the drive member 182 based on the monitoring. The controller (not shown) may be provided in the form of a PC, memory, or the like, and an input value and a control value by a user may be input to the controller (not shown). As the controller (not shown) controls the vertical position (height) of the baffle plate 181, the pressure or plasma density inside the processing space may be controlled.

Meanwhile, the inclined surface s may be formed on the outer wall of the substrate support member 210 instead of the inner wall of the housing 110. That is, the inclined surface s may be formed to correspond to the inner surface of the baffle plate 181.

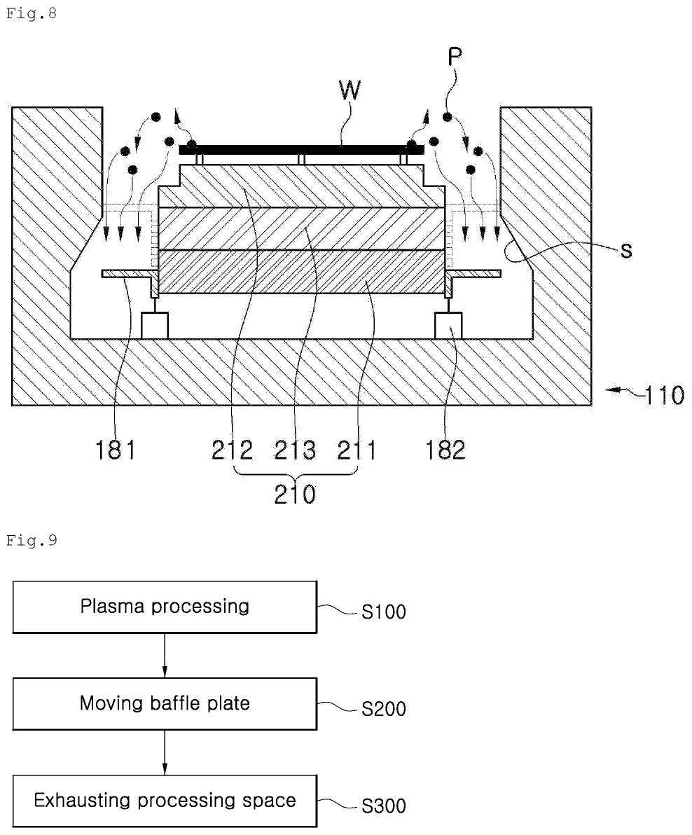

Hereinafter, a process of processing the substrate W using the substrate processing apparatus described above will be described. This embodiment describes a process of plasma processing the substrate W. FIG. 8 is a cross-sectional view showing a process of processing a substrate using the substrate processing apparatus of FIG. 5, and FIG. 9 is a flowchart showing a substrate processing method according to an embodiment of the present disclosure. The substrate processing method illustrated in FIG. 9 may be performed by the substrate processing apparatus illustrated in FIGS. 1 to 2 and 5 to 8.

The substrate processing method according to the embodiment of the present disclosure may include: plasma processing (S100) a substrate by supplying plasma to a substrate W placed on a substrate support unit 200; moving a baffle plate 181 provided to surround the substrate support unit 200 to adjust the vertical position, that is, the height, of the baffle plate 181; and exhausting (S300) a processing space for discharging the used process gas, process by-products from plasma processing, and unused process gas from the processing space.

The plasma processing (S100) is a step of plasma processing the substrate W on the substrate support unit 200 disposed inside the processing space by generating plasma by a plasma generation unit 130 from the process gas supplied to the processing space via the shower head unit 140. At this time, the processing space is characterized in that at least a portion of the inner wall thereof includes an inclined surface s.

The moving (S200) a baffle plate 181 is a step of moving the vertical position of the baffle plate 181 by controlling a drive member 182, and is also a step of changing a gap d between the baffle plate 181 and the inner surface of a housing 110 by moving the baffle plate up and down to change the space between the outer surface of the baffle plate 181 and the processing space. At this time, the vertical position of the baffle plate may be monitored by a position sensor (not shown).

The inner wall of the housing 110 may be formed to have an inclined shape with respect to a region corresponding to a section in which the baffle plate 181 moves up and down by the drive member 182.

For example, the inner wall of the housing 110 may have an inclined shape with a circumference widening from bottom to top with respect to the region corresponding to the section in which the baffle plate 181 moves up and down by the drive member 182. In this case, as the baffle plate 181 descends from the uppermost end of the inclined surface s, the distance between the inner wall of the housing 110 and the baffle plate 181 narrows.

On the other hand, the inner wall of the housing 110 may have an inclined shape with a circumference narrowing from bottom to top with respect to the region corresponding to the section in which the baffle plate 181 moves up and down by the drive member 182. In this case, as the baffle plate 181 descends from the uppermost end of the inclined surface s, the distance between the inner wall of the housing 110 and the baffle plate 181 widens.

Meanwhile, unlike the description above, the inclined surface s may be formed on the outer wall of the substrate support member 210.

As the vertical position of the baffle plate 181 is moved up and down in the step of moving (S200) the baffle plate, plasma confinement and conductance above the baffle plate 181 may be controlled. Accordingly, the residence time of the process gas above the baffle plate 181 may be controlled. In addition, the residence time of the process by-products above the baffle plate 181 may be controlled.

In terms of plasma confinement, the smaller the gap and space between the baffle plate 181 and the inner wall of the housing, the stronger the binding force may be, whereas the larger the gap and space between the baffle plate 181 and the inner wall of the housing, the weaker the binding force may be.

In terms of chamber conductance, by reducing the chamber conductance, the residence time of process gases and process by-products may be increased, which improves the recess selectivity of the substrate to ensure process margins in the Punch, Not Open area of critical dimension (CD).

The exhausting (S300) a processing space is a step of discharging the used process gas, process by-products from plasma processing, and unused process gas from the processing space through the baffle unit 180 and an exhaust hole 111 when the plasma processing the substrate is completed, and may be performed after the plasma processing step (S100) and the baffle plate moving step (S200)

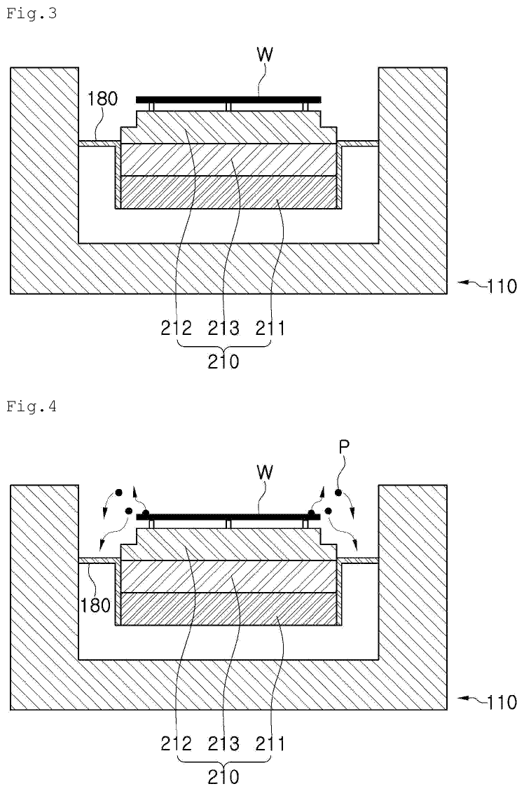

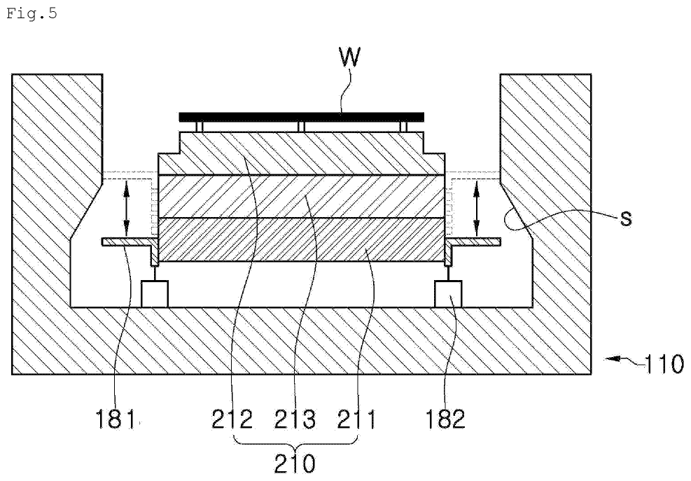

The baffle unit 180 according to various embodiments of the present disclosure and the substrate processing apparatus 100 including the baffle unit 180 have been described above with reference to FIGS. 1 to 9.

The substrate processing apparatus 100 may have various effects due to a configuration of a housing having an inclined surface and an upward/downward movement of a baffle plate, and may adjust variable elements of a process performed within the housing.

To be specific, when the inner wall of the housing has an inclined surface, the following effects may be obtained.

First, the gap between the baffle plate 181 and the inner wall of the housing may be adjusted, and process-induced asymmetry (e.g., swirl flow generated by a pump among various causes of asymmetry) may be improved by using the screen effect.

Second, plasma confinement may be controlled according to the size of a gap between the baffle plate 181 and the inner wall of the housing.

Third, gas conductance may be adjusted. That is, by adjusting the size of the gap between the baffle plate 181 and the inner wall of the housing, it is possible to adjust the degree of air passing through a vacuum state for a certain period of time, thereby improving etch uniformity at an edge area through control of the conductance.

Meanwhile, when the baffle unit 180 is driven up/down, the following effects may be obtained.

First, it becomes possible to induce a change in plasma volume, and accordingly, it becomes possible to control plasma density.

Second, due to the up/down movement of the baffle plate disposed inside the housing having an inclined inner wall, it is possible to control a step-down and degree by adjusting the conductance between the housing and the baffle plate and on the underside of the baffle plate.

In addition to this, various process variables may be created through the above structure, and fine adjustment of the process may be implemented by parameterizing.

To summarize the above contents, the substrate processing apparatus 100 may adjust the distance between the baffle plate 181 and the inner wall of the housing by utilizing the shape of the housing including the inclined inner wall and the up/down driving of the baffle plate 181, and may induce changes in chamber conductance, gas residence time, and plasma volume (distribution). The substrate processing apparatus 100 may control a density between a plasma center and edge by means of the baffle unit 180 to improve etching rate change and etching uniformity.

Although the embodiments of the present disclosure have been described with reference to the above and accompanying drawings, those skilled in the art to which the present disclosure pertains will understand that the present disclosure may be embodied in other specific forms without changing its technical spirit or essential characteristics. Therefore, it should be understood that the embodiments described above are illustrative in all respects and not restrictive.

What is claimed is:

1. A substrate processing apparatus, comprising:
a housing configured to provide a processing space therein;
a substrate support unit configured to support a substrate within the processing space; and
a baffle unit provided to surround a circumference of the substrate support unit,
wherein the baffle unit comprises:
a baffle plate provided to surround the circumference of the substrate support unit and having at least one slit therein; and
a drive member that lifts and moves the baffle plate, and
the housing is provided in a shape capable of changing a size of a space between the processing space and the baffle plate according to a lifting movement of the baffle plate.

2. The substrate processing apparatus of claim 1, further comprising:
a sensor configured to detect a position of the baffle plate; and
a controller configured to control the position of the baffle plate.

3. The substrate processing apparatus of claim 2, wherein an inner wall of the housing has an inclined shape with a circumference thereof widening from bottom to top with respect to a region corresponding to a section in which the baffle plate moves up and down.

4. The substrate processing apparatus of claim 2, wherein an inner wall of the housing has an inclined shape with a circumference thereof narrowing from bottom to top with respect to a region corresponding to a section in which the baffle plate moves up and down.

5. The substrate processing apparatus of claim 2, wherein the controller controls a pressure or plasma density inside the processing space by controlling a height of the baffle plate.

6. The substrate processing apparatus of claim 5, wherein a residence time of a process gas in the processing space is controlled according to the height of the baffle plate.

7. A substrate processing apparatus, comprising:
a housing configured to provide a processing space therein;
a substrate support unit configured to support a substrate within the processing space;
a gas supply unit configured to supply a process gas to the processing space;
a plasma generation unit configured to generate plasma from the process gas; and
a baffle unit provided to surround a circumference of the substrate support unit,
wherein the baffle unit comprises:
a baffle plate provided to surround the circumference of the substrate support unit and having at least one slit therein; and
a drive member that lifts and moves the baffle plate, and
an inner wall of the housing includes an inclined surface so that a changing occurs in a distance between the inner wall of the housing and the baffle plate according to a lifting movement of the baffle plate.

8. The substrate processing apparatus of claim 7, further comprising:
a sensor configured to detect a position of the baffle plate; and
a controller configured to control the position of the baffle plate.

9. The substrate processing apparatus of claim 8, wherein the inner wall of the housing has an inclined shape with a circumference thereof widening from bottom to top with respect to a region corresponding to a section in which the baffle plate moves up and down.

10. The substrate processing apparatus of claim 8, wherein the inner wall of the housing has an inclined shape with a circumference thereof narrowing from bottom to top with respect to a region corresponding to a section in which the baffle plate moves up and down.

11. The substrate processing apparatus of claim 8, wherein the controller controls a pressure or plasma density inside the processing space by controlling a height of the baffle plate.

12. The substrate processing apparatus of claim 11, wherein a residence time of the process gas in the processing space is controlled according to the height of the baffle plate.

13. The substrate processing apparatus of claim 7, wherein the plasma generation unit comprises:
an upper electrode disposed above the substrate;
a lower electrode disposed below the substrate to face the upper electrode in a vertical direction;
an upper power source configured to apply power to the upper electrode; and
a lower power source configured to apply power to the lower electrode.

14. A substrate processing method characterized in that:
plasma is supplied onto a substrate placed on a substrate support unit to treat the substrate,
a baffle plate surrounding the substrate support unit is provided, plasma density above the baffle plate is controlled by adjusting a vertical position of the baffle plate, and
at least a portion of an inner surface of a processing space is formed as an inclined surface so that a space between the baffle plate and the processing space is variable according to a lifting movement of the baffle plate.

15. The substrate processing method of claim 14, wherein the baffle plate is moved up and down by a drive member, and
the vertical position of the baffle plate is monitored by a sensor.

16. The substrate processing method of claim 15, wherein an inner wall of the housing has an inclined shape with a circumference thereof widening from bottom to top with respect to a region corresponding to a section in which the baffle plate moves up and down.

17. The substrate processing method of claim 15, wherein an inner wall of the housing has an inclined shape with a circumference thereof narrowing from bottom to top with respect to a region corresponding to a section in which the baffle plate moves up and down.

18. The substrate processing method of claim 15, wherein conductance above the baffle plate is controlled by moving a position of the baffle plate up and down.

19. The substrate processing method of claim 18, wherein a residence time of a process gas above the baffle plate is controlled by controlling the conductance above the baffle plate.

20. The substrate processing method of claim 18, wherein a residence time of a process by-products above the baffle plate is controlled by controlling the conductance above the baffle plate.
